(19) United States
(12) Patent Application Publication
(10) Pub. No.: US 2026/0282934 A1
(43) Pub. Date: Sep. 17, 2026

(54) ELECTRONIC DEVICE

(71) Applicant: Advanced Semiconductor Engineering, Inc., Kaohsiung (TW)

(72) Inventors: Yuanhao YU, Kaohsiung (TW); Wei Shuen KAO, Kaohsiung (TW)

(73) Assignee: Advanced Semiconductor Engineering, Inc., Kaohsiung (TW)

(21) Appl. No.: 19/082,162

(22) Filed: Mar. 17, 2025

(51) Int. Cl. H01L 23/66; H01L 23/498; H01L 23/538; H01L 23/552; H01L 25/18; H01Q 1/38

(52) U.S. Cl. CPC H10W 44/20; H01Q 1/38; H10W 42/20; H10W 70/614; H10W 70/635; H10W 90/00; H10W 44/209; H10W 44/248

(57) ABSTRACT

The present disclosure relates to an electronic device. The electronic device includes a substrate and a chip antenna disposed over the substrate at a first elevation with respect to the substrate. The first elevation is greater than a thickness of the chip antenna. The chip antenna is configured to radiate a first signal through a first electrical path.

### BACKGROUND

### 1. Technical Field

The present disclosure generally relates to an electronic device, and more particularly to an electronic device including an elevated chip antenna.

### 2. Description of the Related Art

In electronic products where chip antennas are packaged on a substrate, the chip antenna is constrained by the height and area of the package. Although a clearance zone is arranged, the signal quality is still affected by surrounding components. Therefore, an improved electronic device including chip antenna is called for.

### SUMMARY

In some embodiments, an electronic device includes a substrate and a chip antenna disposed over the substrate at a first elevation with respect to the substrate. The first elevation is greater than a thickness of the chip antenna. The chip antenna is configured to radiate a first signal through a first electrical path.

In some embodiments, an electronic device includes a first antenna and a second antenna. The first antenna is configured to generate a first signal at a first frequency and the second antenna configured to generate a second signal at a second frequency different from the first frequency. The first antenna and the second antenna share an electrical path.

In some embodiments, an electronic device includes a substrate, a chip antenna, and a monopole antenna. The chip antenna is disposed on the substrate at a first elevation with respect to the substrate. The monopole antenna is disposed on the substrate at a second elevation with respect to the substrate, different from the first elevation.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1 is a three-dimensional (3D) schematic diagram of an electronic device, in accordance with some embodiments of the present disclosure.

FIG. 2 is a three-dimensional (3D) schematic diagram of an electronic device, in accordance with some embodiments of the present disclosure.

FIG. 3 is a three-dimensional (3D) schematic diagram of an electronic device, in accordance with some embodiments of the present disclosure.

FIG. 4 is a cross-section of an electronic device, in accordance with some embodiments of the present disclosure.

FIG. 5A, FIG. 5B, FIG. 5C, FIG. 5D, FIG. 5E, FIG. 5F, and FIG. 5G illustrate one or more operations of a method for manufacturing an electronic device, in accordance with some embodiments of the present disclosure.

FIG. 6A, FIG. 6B, FIG. 6C, and FIG. 6D illustrate one or more operations of a method for manufacturing an electronic device, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

Embodiments of the present disclosure discuss an electronic device including elevated chip antenna. The chip antenna is elevated with the conductive elements, such as pillars, wires, or the like. The elevated chip antenna can obtain more clearance area, i.e., the space under the chip antenna. Owing to the additional clearance area, the efficiency of the antenna (such as the gain thereof) can be improved. In addition to the chip antenna, the electronic device can further include a monopole antenna disposed in the clearance zone and sharing an electrical path with the chip antenna. Moreover, the monopole antenna can operate at a frequency different from the chip antenna, such that the electronic device can be configured to have better performance in different bandwidths.

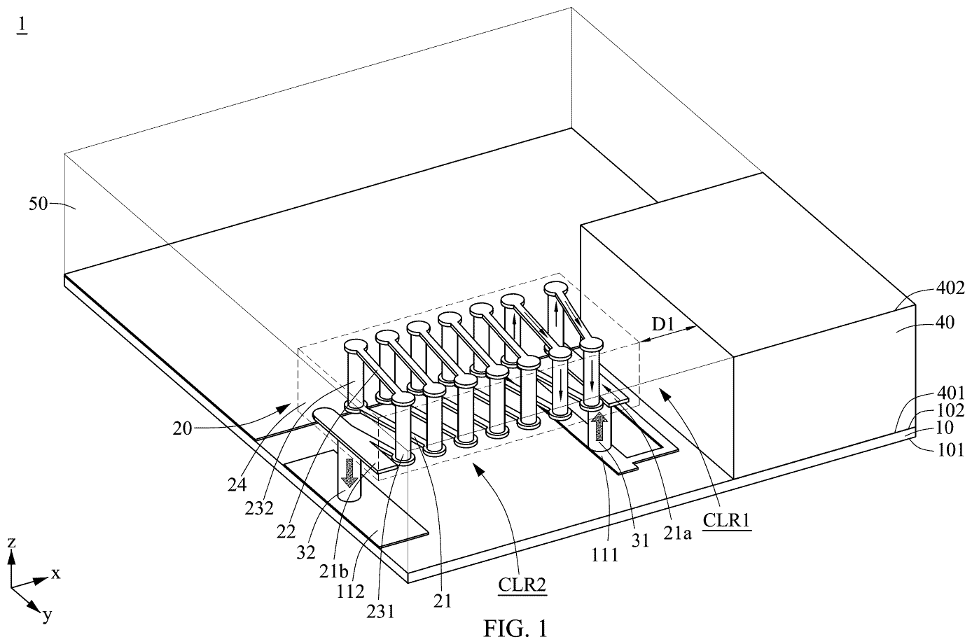

FIG. 1 is a three-dimensional (3D) schematic diagram of an electronic device 1, in accordance with some embodiments of the present disclosure. The electronic device 1 may include a substrate 10, a chip antenna 20, one or more conductive pillars 31 and 32, an electronic component 40, and an encapsulant 50. In some embodiments, the electronic device 1 may further include other elements disposed on the substrate 10, but are omitted for clarity.

The electronic device 1 may be or include antenna in package (AiP), antenna on package (AoP), or the like. The electronic device 1 may operate within multiple bandwidths. For example, the electronic device 1 may be a tri-band AoP. In some embodiments, the electronic device 1 may be applicable to ultra-wide bandwidth (UWB), Bluetooth, or Wi-Fi. For example, the electronic device 1 may be applicable to Wi-Fi 6, Wi-Fi 6E, Wi-Fi 7, or the like. In some embodiments, the electronic device 1 may be a multiple bandwidths communication device or a GPS positioning communication device. In some embodiments, the electronic device 1 may be a mobile phone or a smart watch.

The proposed electronic device 1 features an elevated chip antenna. This chip antenna is raised using conductive elements like pillars, wires, or similar structures. By elevating the chip antenna, additional clearance space can be created underneath the chip antenna. This extra clearance can enhance the efficiency of the antenna, including its gain.

Referring to FIG. 1, the substrate 10 may have a bottom surface 101 and a top surface 102 opposite to the bottom surface 101. The substrate 10 may include, for example, a printed circuit board (PCB), such as a paper-based copper foil laminate, a composite copper foil laminate, or a polymer-impregnated glass-fiber-based copper foil laminate. In some embodiments, the substrate 10 may include conductive layers 111 and 112 on the top surface 102. The conductive layers 111 and 112 may be patterned. The conductive layers 111 and 112 may be separated by a dielectric material.

The chip antenna 20 may be disposed on the top surface 102 of the substrate 10. In some embodiments, the chip antenna 20 may be disposed over the substrate 10 without contacting the substrate 10. The chip antenna 20 may be disposed on the conductive layers 111 and 112 of the substrate 10. The chip antenna 20 may be a cuboid with one or more terminals.

The chip antenna 20 may be electrically connected to the substrate 10. In some embodiments, the conductive pillar 31 may be disposed between the substrate 10 and the chip antenna 20. The conductive pillar 31 may connect the chip antenna 20 to the conductive layer 111 of the substrate 10. The conductive pillar 31 may be substantially perpendicular to the substrate 10. The conductive pillar 31 may include a conductive via, a conductive wire, or other suitable conductive interconnectors. For example, the conductive pillar 31 may include a copper (Cu) pillar.

In some embodiments, the conductive pillar 32 may be disposed between the substrate 10 and the chip antenna 20. The conductive pillar 32 may connect the chip antenna 20 to the conductive layer 112 of the substrate 10. The conductive pillar 32 may be spaced apart from the conductive pillar 31 and connected to the chip antenna 20. That is, the conductive pillars 31 and 32 may be connected to two terminals of the chip antenna 20, respectively. The chip antenna 20 may be elevated by the conductive pillars 31 and 32. When the chip antenna 20 is elevated, the space underneath the same can be referred to as a clearance zone CLR2. The distances and/or heights of elements adjacent to the chip antenna 20 may affect the performance of the chip antenna 20, such as the radiation pattern and gain. Therefore, the performance of the chip antenna 20 can be enhanced with larger clearance zone CLR1 and the additional clearance zone CLR2.

In some embodiments, the conductive pillar 31 may be an input of the chip antenna 20, and the conductive pillar 32 may be the output of the chip antenna 20. One of the conductive pillars 31 and 32 may be a feeding point of the chip antenna 20. The conductive pillar 32 may be substantially perpendicular to the substrate 10. The conductive pillar 32 may include a conductive via, a conductive wire, or other suitable conductive interconnectors. For example, the conductive pillar 32 may include a copper (Cu) pillar.

In some embodiments, the chip antenna 20 may be configured to radiate a first signal at a first frequency through a first electrical path. The chip antenna 20 is configured to carry a first current from the conductive pillar 31 to the conductive pillar 32. In some embodiments, the first electrical path may include the conductive pillar 31, the chip antenna 20, and the conductive pillar 32. In some embodiments, the chip antenna 20 may be electrically connected to a radio frequency integrated circuit (RFIC) (not shown), which may be also disposed on the substrate 10. In some embodiments, the monopole antenna 60 may operate within the bandwidth of 2.4 GHz or 2.5 GHz. In some embodiments, the chip antenna 20 may function at the frequency of 2.4, 2.45, or 2.5 GHz.

In some embodiments, the chip antenna 20 may include a first conductive layer 21, a second conductive layer 22, a plurality of conductive structures 231 and 232, and an encapsulant 24.

Each of the first conductive layer 21 and the second conductive layer 22 may be patterned. The first conductive layer 21 and the second conductive layer 22 may include conductive traces extending in an X-Y plane. The first conductive layer 21 may include an input trace 21a, an output trace 21b and several conductive traces between the input trace 21a and output trace 21b extending in parallel. The input trace 21a and output trace 21b may be parallel but non-parallel to the conductive traces therebetween. The input trace 21a may be connected to the conductive layer 111 through the conductive pillar 31. The output trace 21b may be connected to the conductive layer 112 through the conductive pillar 32.

The second conductive layer 22 may be disposed on the first conductive layer 21. The second conductive layer 22 may include multiple conductive traces extending in parallel. In some embodiments, the conductive traces of the second conductive layer 22 may extend in a direction different from those of the first conductive layer 21. In some embodiments, the first conductive layer 21 and the second conductive layer 22 may each include a conductive material such as a metal or metal alloy. Examples of the conductive material include gold (Au), silver (Ag), aluminum (Al), copper (Cu), or an alloy thereof.

The plurality of conductive structures 231 and 232 may be disposed between the first conductive layer 21 and the second conductive layer 22. The conductive structures 231 and 232 extend along the Z-axis. The plurality of conductive structures 231 and 232 may connect the first conductive layer 21 to the second conductive layer 22. The conductive structures 231 may be arranged in a first row, and the conductive structures 232 may be arranged in a second row, wherein the first row and the second row extend in parallel and arranged at opposite sides of the chip antenna 20. The conductive structures 231 and 232 may connect the conductive traces of the first conductive layer 21 to the conductive traces of the second conductive layer 22 such that a coil can be formed. Under operation, the electrical current may pass from the conductive pillar 31 through the coil (i.e., the first conductive layer 21, the second conductive layer 22, and the conductive structures 231 and 232) to the conductive pillar 32.

The conductive structures 231 and 232 may be conductive structures, conductive vias, or other suitable conductive interconnectors. In some embodiments, the conductive structures 231 and 232 may each include a conductive material such as a metal or metal alloy. Examples of the conductive material include gold (Au), silver (Ag), aluminum (Al), copper (Cu), or an alloy thereof.

The encapsulant 24 may encapsulate or cover the first conductive layer 21, the second conductive layer 22, the conductive structures 231 and 232. In some embodiments, the input trace 21a and the output trace 21b of the first conductive layer 21 of the chip antenna 20 may be partially exposed by the encapsulant 24 so as to connect to the conductive pillars 31 and 32, respectively. In some embodiments, the encapsulant 24 may include an epoxy resin having fillers dispersed therein, a molding compound (e.g., an epoxy molding compound or other molding compound), PI, a phenolic compound or material, a polymer material with silicone dispersed therein, or a combination thereof.

The electronic component 40 may be disposed on the substrate 10. The electronic component 40 may have a bottom surface 401 and a top surface 402 opposite to the bottom surface 401. The bottom surface 401 of the electronic component 40 may be lower than a bottom surface of the chip antenna 20. The electronic component 40 may be spaced apart from the chip antenna 20 by a distance D1. The space between the electronic component 40 and the chip antenna 20 may be referred to as a clearance zone CLR1. The performance of the chip antenna 20 improves with an increase in the size of the clearance zone CLR1. In some embodiments, the electronic component 40 may be an active device that is not directly relevant to the chip antenna 20. For example, the electronic component 40 may be an oscillator.

The encapsulant 50 may be disposed on the top surface 102 of the substrate 10. The encapsulant 50 may encapsulate or cover the chip antenna 20, the conductive pillars 31 and 32, and the electronic component 40. In some embodiments, the encapsulant 50 may include an epoxy resin having fillers dispersed therein, a molding compound (e.g., an epoxy molding compound or other molding compound), PI, a phenolic compound or material, a polymer material with silicone dispersed therein, or a combination thereof.

The electronic device 1 proposes the chip antenna 20 elevated by the conductive pillars 31 and 32. After elevated, the peak gain of the chip antenna 20 may improve about 2 to 3 dB. Comparing to the configuration that the chip antenna is directly bonded to the substrate, the peak gain of the elevated chip antenna 20 can be enhanced from −2.95 dB to −0.55 dB with maintaining the same size for the electronic component 40. The desired gain of the chip antenna 20 may be in a range of −1 dB to 5 dB, preferably, a range of 0 dB to 3 dB, and more preferably, a range of 0 dB to 2 dB. For example, the peak gain of the chip antenna 20 may be about −0.55 dB, 0.21 dB, or 0.91 dB.

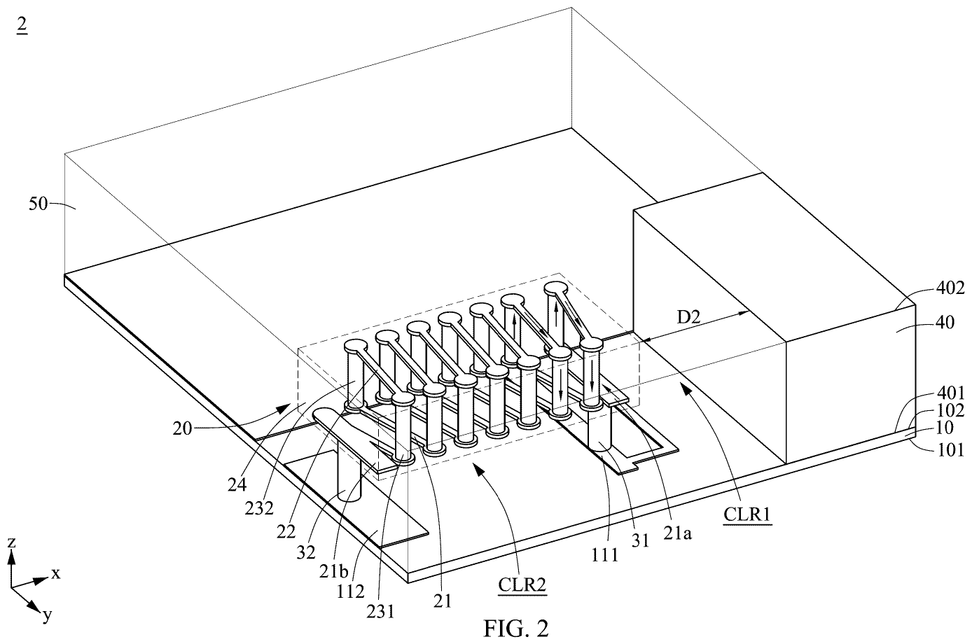

FIG. 2 is a three-dimensional (3D) schematic diagram of an electronic device 2, in accordance with some embodiments of the present disclosure. The electronic device 2 is similar to the electronic device 1 in FIG. 1, and the difference therebetween is the size of the electronic component 40. With a smaller electronic component 40, the clearance zone CLR1 can be enlarged correspondingly. That is, the electronic component 40 can be spaced apart from the chip antenna 20 by a distance D2. The distance D2 may be different from the distance D1 of FIG. 1. The distance D2 may be greater than the distance D1. For example, the distance D1 may be 5 mm, and the distance D2 may be 6 or 7 mm.

As proposed in FIG. 2 that the size of the electronic component 40 is reduced, the peak gain of the elevated chip antenna 20 can be 0.21 dB, while the peak gain of the chip antenna directly bonded to the substrate can be −2.41 dB. Therefore, the peak gain of the chip antenna 20 may improve about 2.62 dB. In another embodiment, if the size of the electronic component 40 is further reduced, the peak gain of the elevated chip antenna 20 can be 0.91 dB, while the peak gain of the chip antenna directly bonded to the substrate can be −2.01 dB. Therefore, the peak gain of the chip antenna 20 may improve about 3 dB.

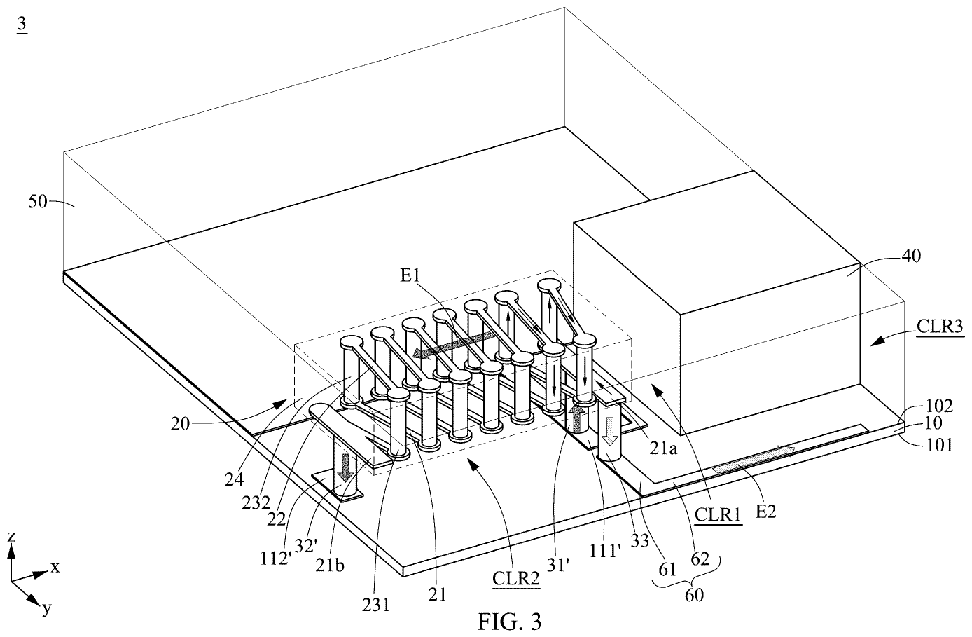

FIG. 3 is a three-dimensional (3D) schematic diagram of an electronic device 3, in accordance with some embodiments of the present disclosure. The electronic device 3 is similar to the electronic device 1 in FIG. 1, and the difference therebetween is that the electronic device 3 further includes a monopole antenna 60, an additional conductive pillar 33, and a shrunk electronic component 40. In some embodiments, the size of the electronic component 40 may be reduced along Y-axis to create an additional clearance zone CLR3. Accordingly, the gain of the chip antenna 20 can be further enhanced compared to that of electronic device 1 of FIG. 1 with more clearance zones.

Referring to FIG. 3, the chip antenna 20 may include three terminals connected to conductive layers 111′ and 112′ and the monopole antenna 60, respectively. Each of the terminals of the chip antenna 20 may be connected to a conductive pillar 31′, 32′, or 33. The chip antenna 20 may be connected to the conductive layer 111′ through the conductive pillar 31′. The chip antenna 20 may be connected to the conductive layer 112′ through the conductive pillar 32′. The chip antenna 20 may be connected to the monopole antenna 60 through the conductive pillar 33. The conductive layers 111′ and 112′ may be similar to the conductive layers 111 and 112 differing in arrangements/shapes. The conductive pillars 31′, 32′, and 33 may be similar to the conductive pillars 31 and 32 differing in locations.

The conductive pillar 33 may be disposed between the chip antenna 20 and the substrate 10. The conductive pillar 33 may be spaced apart from the conductive pillars 31′ and 32′. In some embodiments, the conductive pillars 31′ and 33 may be disposed at opposite sides of the chip antenna 20 along Y-axis. In some embodiments, the conductive pillars 31′ and 33 may be disposed at one side of the chip antenna 20, and the conductive pillar 32′ may be disposed at the opposite side along X-axis.

In some embodiments, the monopole antenna 60 may be disposed on the top surface 102 of the substrate 10. The monopole antenna 60 may include a conductive pattern disposed on or embedded in the substrate 10. The monopole antenna 60 may be disposed within the clearance zone CLR1 and the additional clearance zone CLR3. The monopole antenna 60 may be spaced apart from the electronic component 40. The monopole antenna 60 may be connected to the chip antenna 20 through the conductive pillar 33. The monopole antenna 60 may extend in a direction substantially perpendicular to the conductive pillar 33. The chip antenna 20 and the monopole antenna 60 may share the same feeding point (i.e., the conductive pillar 31′).

As the chip antenna 20 is elevated by the conductive pillars 31′, 32′, and 33, the chip antenna 20 may be at a first elevation with respect to the substrate 10, and the monopole antenna 60 may be at a second elevation with respect to the substrate 10, specifically at approximately the top surface 102 of the substrate 10, which is lower than the first elevation. In some embodiments, the bottom surface of the monopole antenna 60 may be lower than the bottom surface of the chip antenna 20. The top surface of the monopole antenna 60 may be lower than the bottom surface of the chip antenna 20. In some embodiments, the monopole antenna 60 may each include a conductive material such as a metal or metal alloy. Examples of the conductive material include gold (Au), silver (Ag), aluminum (Al), copper (Cu), or an alloy thereof.

In some embodiments, the monopole antenna 60 includes a first portion 61 and a second portion 62 connected to the first portion 61. The first portion 61 may be connected to the chip antenna 20 through the conductive pillar 33. The first portion 61 may extend in the clearance zone CLR1. The second portion 62 may extend in the clearance zone CLR1 and the additional clearance zone CLR3 and parallel to an edge of the electronic component 40. The second portion 62 may extend along a direction different from the first portion 61. For example, the first portion 61 may be substantially perpendicular to the second portion 62. The first portion 61 is shorter than the second portion 62. In some embodiments, the width of the second portion 62 may be less than the width of the first portion 61. The second portion 62 may be the transmitting end of the monopole antenna 60. In some embodiments, the second portion 62 may not overlap the chip antenna 20 vertically (along Z-axis).

In some embodiments, the chip antenna 20 may be configured to radiate a first signal at a first frequency through a first electrical path. In some embodiments, the first electrical path may include the conductive pillar 31′, the chip antenna 20, and the conductive pillar 32′. In some embodiments, the chip antenna 20 may be electrically connected to a RFIC (not shown). In some embodiments, the chip antenna 20 may be electrically connected to the RFIC through the conductive layer 111′. In some embodiments, the chip antenna 20 may operate within the bandwidths of 2.4 GHz or 2.5 GHz. In some embodiments, the chip antenna 20 may function at the frequency of 2.4, 2.45, or 2.5 GHz.

Since the size of the electronic component 40 is reduced to create the additional clearance zone CLR3, the peak gain of the elevated chip antenna 20 can enhanced about or more than 3 dB at the bandwidths of 2.4 GHz and 2.5 GHz. For example, the peak gain of the chip antenna 20 may be about 2.88 dB, 3.08 dB, 3.81 dB, or 3.99 dB.

The monopole antenna 60 may be configured to radiate a second signal at a second frequency through a second electrical path. In some embodiments, the first frequency of the first signal radiated by the chip antenna 20 may be different from the second frequency of the second signal radiated by the monopole antenna 60. The second electrical path may include the conductive pillar 31′, the chip antenna 20, the conductive pillar 33, and the monopole antenna 60. In some embodiments, the second electrical path may be different from the first electrical path. For example, the second electrical path is shorter than the first electrical path. In some embodiments, the chip antenna 20 and the monopole antenna 60 may share an electrical path, which may include a part of the chip antenna 20 (such as, the input trace 21a). In some embodiments, the monopole antenna 60 may be electrically connected to the RFIC (not shown).

In some embodiments, the monopole antenna 60 may operate within the bandwidths of 5 GHz, 6 GHz, or 7 GHz. In some embodiments, the monopole antenna 60 may function at the frequency of 5.15, 5.55, 5.85, 6.85, or 7.125 GHz. Integrating the monopole antenna 60, the peak gain of the electronic device 3 can improve about 1 dB, 1.5 dB, 2 dB, 5 dB, 7 dB, or even 10 dB within the bandwidth of 5 GHz, 6 GHz, or 7 GHz. Owing to the monopole antenna 60, the peak gain of the electronic device 3 can be greater than 1 dB within the bandwidths of 5 GHz, 6 GHz, or 7 GHz. In some embodiments, the peak gain of the electronic device 3 may be in a range of 1 dB to 4 dB within the bandwidth of 5 GHz.

The chip antenna 20 may be served to radiate signals within the bandwidth of 2.4 GHz and 2.5 GHz, and the monopole antenna 60 may be served to radiate signals within the bandwidth of 5 GHz, 6 GHz, or 7 GHz. In some embodiments, the peak gain of the electronic device 3 may be 3.99 dB when operating at the frequency of 2.4 GHz. The peak gain of the electronic device 3 may be 2.88 dB when operating at the frequency of 2.5 GHz. The peak gain of the electronic device 3 may be 1.1 dB when operating at the frequency of 5.15 GHz. The peak gain of the electronic device 3 may be 3.96 dB when operating at the frequency of 5.55 GHz. The peak gain of the electronic device 3 may be 3.92 dB when operating at the frequency of 5.85 GHz. The peak gain of the electronic device 3 may be 2.23 dB when operating at the frequency of 6.85 GHz. The peak gain of the electronic device 3 may be 2.43 dB when operating at the frequency of 7.125 GHz.

The chip antenna 20 may be configured to carry or conduct a first current. In some embodiments, the first current may flow at the first elevation with respect to the substrate 10. The first current may flow within the elevation of the top surface and the bottom surface of the chip antenna 20. The first current may pass through the coil of the chip antenna 20 (i.e., the first conductive layer 21, the second conductive layer 22, and the conductive structures 231 and 232). In some embodiments, the first current may be an eddy current toward a first direction E1. That is, the first current may be input from the conductive pillar 31′ though the coil of the chip antenna 20, and then output to the conductive pillar 32′.

The monopole antenna 60 may be configured to carry or conduct a second current flowing at the second elevation with respect to the substrate 10 (such as the elevation of the top surface 102 of the substrate 10). The second elevation is different from the first elevation. For example, the second elevation is lower than the first elevation. In some embodiments, the second current may flow toward a second direction E2 different from the first direction E1. The second direction E2 is opposite to the first direction E1.

In some embodiments, the encapsulant 50 may disposed on the substrate 10, and encapsulate or cover the chip antenna 20, the electronic component 40, and the monopole antenna 60.

The electronic device 3 proposes the elevated chip antenna 20 and the monopole antenna 60 disposed in the clearance zones CLR1 and CLR3, wherein the monopole antenna 60 shares an electrical path with the chip antenna 20. The chip antenna 20 and the monopole antenna 60 can be configured to carry electrical currents that flow in varying directions, elevations, and lengths. By elevating the chip antenna 20, additional clearance zone could be created underneath the chip antenna 20, which enhances the antenna's efficiency, including its gain. Moreover, the chip antenna 20 and the monopole antenna 60 can operate at different bandwidths, allowing the electronic device to perform better across various bandwidths.

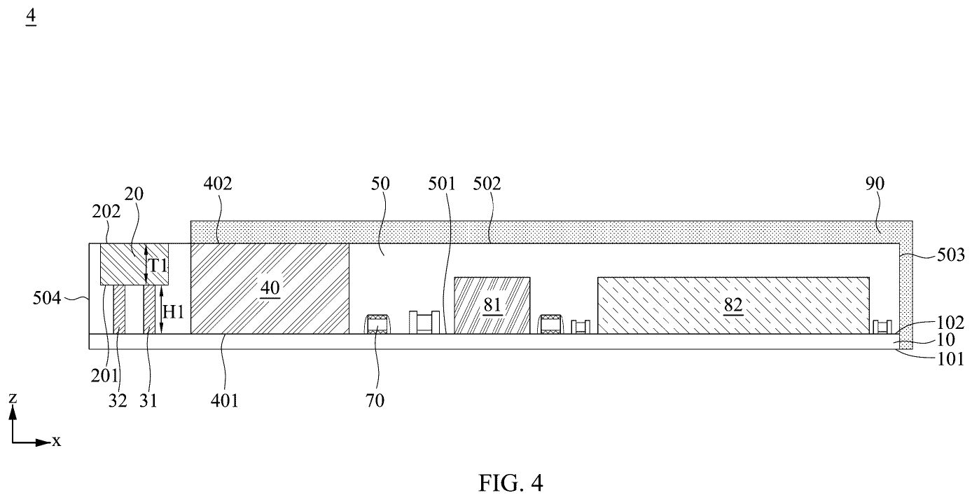

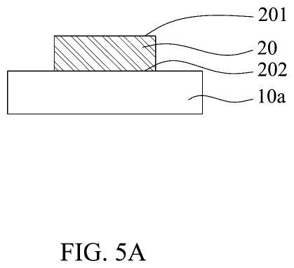

FIG. 4 is a cross-section of an electronic device 4, in accordance with some embodiments of the present disclosure. FIG. 4 may show an exemplary cross-section of the electronic device 1, 2, or 3. The electronic device 4 includes a substrate 10, a chip antenna 20, one or more conductive pillars 31 and 32, an electronic component 40, an encapsulant 50, one or more passive devices 70, active devices 81 and 82, and a shielding layer 90. The substrate 10, the chip antenna 20, the conductive pillars 31 and 32, the electronic component 40, and the encapsulant 50 are substantially the same as those shown in FIGS. 1, 2, and 3, and thus the details thereof are omitted for clarity. In some embodiments, the electronic device 4 may include the monopole antenna 60 (not shown in FIG. 4) disposed on the substrate 10 and encapsulated by the encapsulant 50.

Referring to FIG. 4, the chip antenna 20 may be disposed on the substrate 10 and encapsulated by the encapsulant 50. The chip antenna 20 may have a bottom surface 201 and a top surface 202 opposite to the bottom surface 201. The chip antenna 20 may have a thickness T1. The conductive pillars 31 and 32 may be connected to the bottom surface 201 of the chip antenna 20. The chip antenna 20 may be elevated by the conductive pillars 31 and 32. The chip antenna 20 may be at a first elevation H1 with respect to the substrate 10, i.e., the lengths of the conductive pillars 31 and 32. The performance of the chip antenna 20 improves as the first elevation H1 increases. In some embodiments, the first elevation H1 may be greater than the thickness T1 of the chip antenna 20.

The encapsulant 50 may have a bottom surface 501 and a top surface 502 opposite to the bottom surface 501. The bottom surface 501 of the encapsulant 50 may be substantially coplanar with the top surface 102 of the substrate 10. In some embodiments, the top surface 202 of the chip antenna 20 may be exposed by the encapsulant 50. The top surface 502 of the encapsulant 50 may be substantially aligned with the top surface 202 of the chip antenna 20. In another embodiment, the encapsulant 50 may cover the top surface 202 of the chip antenna 20 (not shown).

In some embodiments, the electronic component 40 may be disposed on the substrate 10 and encapsulated by the encapsulant 50. The electronic component 40 may have a bottom surface 401 and a top surface 402 opposite to the bottom surface 401. The bottom surface 401 may be lower than the bottom surface 201 of the chip antenna 20. In some embodiments, the top surface 402 of the electronic component 40 may be substantially aligned or coplanar with the top surface 202 of the chip antenna 20.

In some embodiments, the top surface 402 of the electronic component 40 may be exposed by the encapsulant 50. The top surface 402 of the electronic component 40 may be substantially aligned with the top surface 502 of the encapsulant 50. In another embodiment, the encapsulant 50 may cover the top surface 402 of the electronic component 40 (not shown).

In some embodiments, one or more passive devices 70 may be disposed on the top surface 102 of the substrate 10 and encapsulated by the encapsulant 50. The passive devices 70 may be disposed at a side of the electronic component 40 different from the chip antenna 20. That is, the electronic component 40 may be disposed between the chip antenna 20 and the passive devices 70. The passive devices 70 may be resistors, capacitors, inductors, or a combination thereof.

In some embodiments, the active devices 81 and 82 may be disposed on the top surface 102 of the substrate 10 and encapsulated by the encapsulant 50. The active devices 81 and 82 may be disposed at a side of the electronic component 40 different from the chip antenna 20. That is, the electronic component 40 may be disposed between the chip antenna 20 and the active devices 81 and 82. The active device 81 may be disposed between the electronic component 40 and the active device 82. In some embodiments, some of the passive devices 70 may be disposed between the electronic component 40 and the active device 81. Some of the passive devices 70 may be disposed between the active device 81 and the active device 82. Some of the passive devices 70 may be disposed between an edge of the substrate 10 and the active device 82. The active devices 81 and 82 may include an IC or a die, such as an application-specific integrated circuit (ASIC), a radio frequency integrated circuit (RFIC), or the like. The thickness of the active devices 81 and 82 may be greater than the thickness of the passive devices 70.

The shielding layer 90 may be disposed on the encapsulant 50 and cover a lateral surface 503 of the encapsulant 50 and a lateral surface of the substrate 10. The shielding layer 90 may partially cover the top surface 502 of the encapsulant 50. The shielding layer 90 may cover the electronic component 40, the passive devices 70, and the active devices 81 and 82. In some embodiments, the shielding layer 90 may be disposed on and in contact with the top surface 402 of the electronic component 40. The shielding layer 90 has an end aligned with the electronic component 40. The shielding layer 90 may expose the chip antenna 20. In some embodiments, the shielding layer 90 may expose the monopole antenna 60 (if any). The shielding layer 90 may expose a lateral surface 504 of the encapsulant 50 opposite to the lateral surface 503. In some embodiments, the ground element (not shown) of the substrate 10 may be electrically connected to the shielding layer 90.

The shielding layer 90 may be or include a conductive film, e.g., for example, aluminum (Al), copper (Cu), chromium (Cr), tin (Sn), gold (Au), silver (Ag), nickel (Ni), a mixture, an alloy, or other combination thereof. The shielding layer 90 may include multiple conductive layers. In some embodiments, the shielding layer 90 may be formed by deposition, such as the physical vapor deposition (PVD). The shielding layer 90 may provide the electromagnetic interference (EMI) shielding effect.

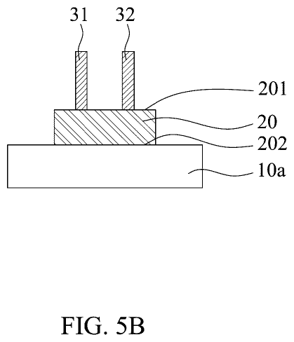

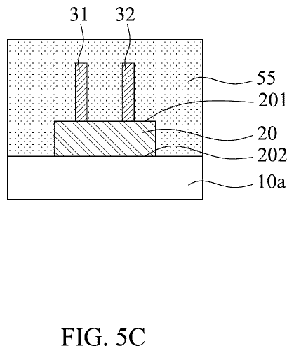

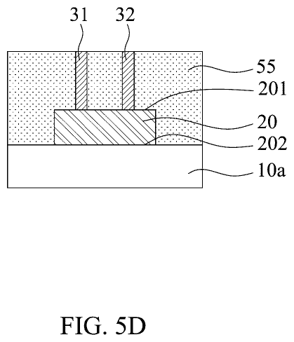

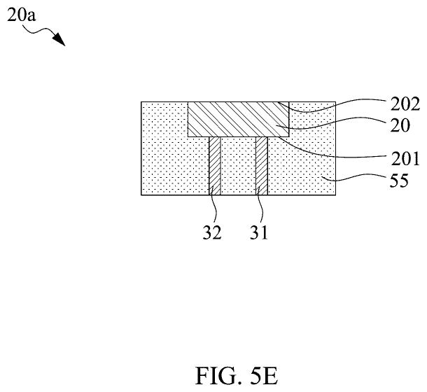

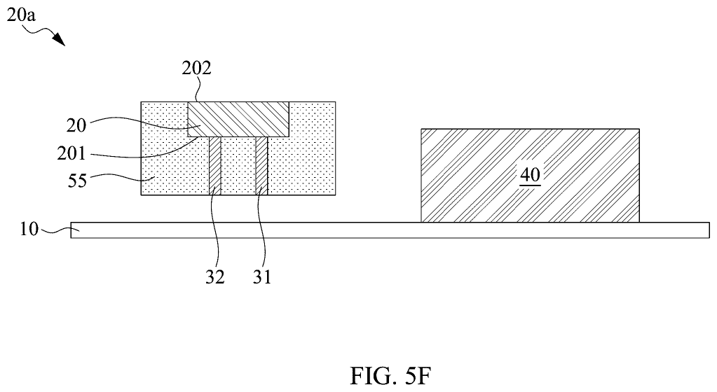

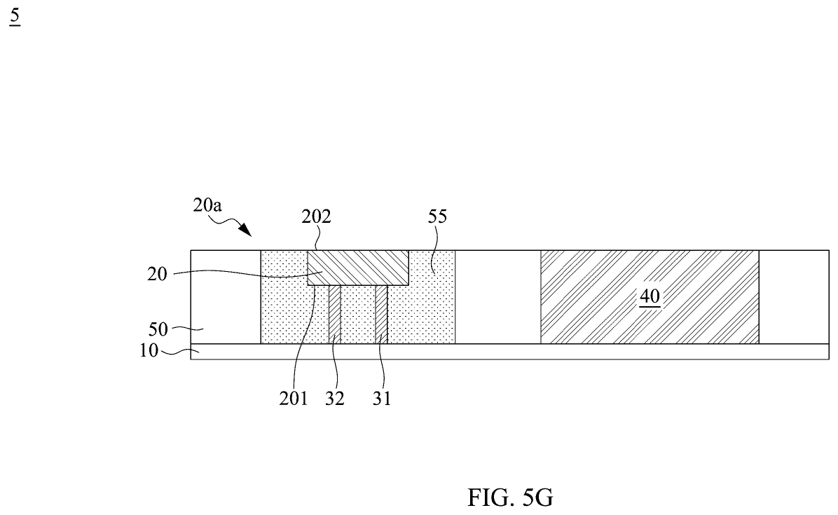

FIG. 5A, FIG. 5B, FIG. 5C, FIG. 5D, FIG. 5E, FIG. 5F, and FIG. 5G illustrate one or more operations of a method for manufacturing an electronic device 5, in accordance with some embodiments of the present disclosure.

Referring to FIG. 5A, a carrier 10a is provided with a chip antenna 20 disposed thereon. In some embodiments, the chip antenna 20 may have a surface 201 and a surface 202 opposite to the surface 201, wherein the surface 202 of the chip antenna 20 may be disposed on the carrier 10a. In some embodiments, the chip antenna 20 may be attached to the carrier 10a.

Referring to FIG. 5B, conductive pillars 31 and 32 may be disposed on the surface 201 of the chip antenna 20. The conductive pillars 31 and 32 may be formed on the surface 201 of the chip antenna 20 through wire-bond process.

Referring to FIG. 5C, an encapsulant 55 may be formed on the carrier 10a to encapsulate the chip antenna 20 and the conductive pillars 31 and 32. The encapsulant 55 may be formed by a molding process.

Referring to FIG. 5D, the encapsulant 55 may be grinded to form a planar top surface and to expose the conductive pillars 31 and 32.

Referring to FIG. 5E, a chip antenna unit 20a including the chip antenna 20, may be removed from the carrier 10a.

Referring to FIG. 5F, the chip antenna unit 20a may be disposed on a substrate 10, on which an electronic component 40 disposed. In some embodiments, the substrate 10 may include other elements disposed thereon that are omitted for clarity. The chip antenna unit 20a may be attached to the substrate 10. For example, the chip antenna unit 20a may be formed on the substrate 10 through a surface mount assembly (SMT) process.

Referring to FIG. 5G, the chip antenna unit 20a and the electronic component 40 may be encapsulated by an encapsulant 50, to form an electronic device 5. The encapsulant 50 may be formed by a molding process and a grinding process. In some embodiments, the top surface of the chip antenna 20 and the top surface of the electronic component 40 may be exposed by the encapsulant 50. The encapsulant 50 may encapsulates the chip antenna unit 20a. That is, the encapsulant 50 may cover and encapsulate the chip antenna 20 and the encapsulant 55. The material of the encapsulant 50 may be the same as the encapsulant 55. In some embodiments, a monopole antenna 60 may be disposed on the substrate 10 (not shown) and encapsulated by the encapsulant 50. The electronic device 5 shown in FIG. 5G may be an exemplary cross-section of the electronic device 1, 2, or 3.

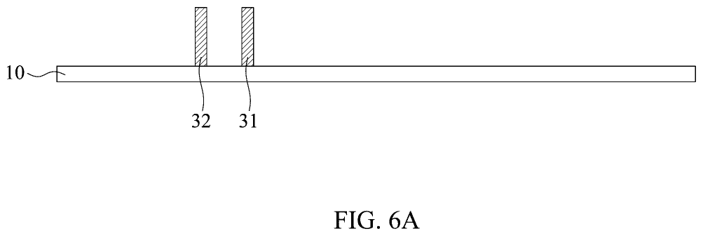

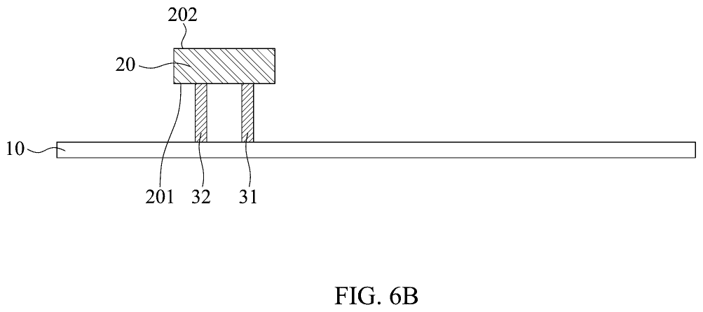

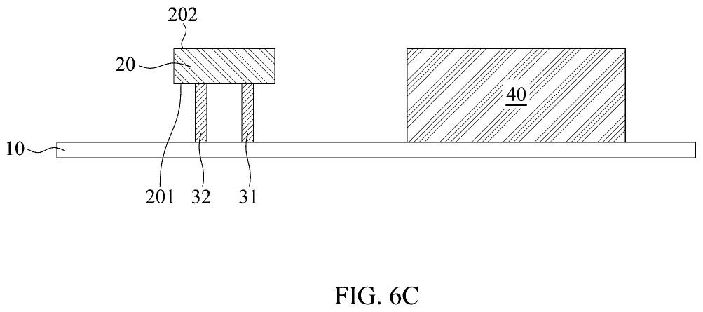

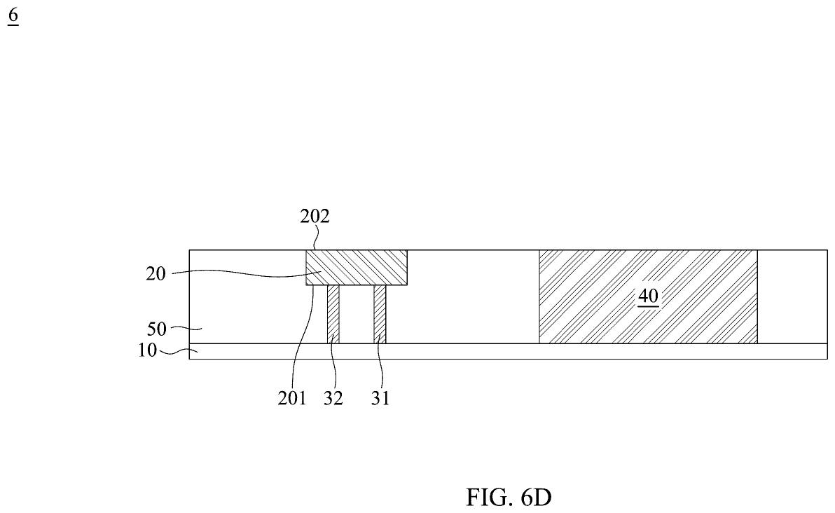

FIG. 6A, FIG. 6B, FIG. 6C, and FIG. 6D illustrate one or more operations of a method for manufacturing an electronic device 6, in accordance with some embodiments of the present disclosure.

Referring to FIG. 6A, two conductive pillars 31 and 32 may be disposed on the top surface of the substrate 10. The conductive pillars 31 and 32 may include copper clips. The conductive pillars 31 and 32 may be formed on the substrate 10 through a surface mount assembly (SMT) process.

Referring to FIG. 6B, a chip antenna 20 may be disposed on the substrate 10 and connected to the conductive pillars 31 and 32. The chip antenna 20 may be formed on the substrate 10 through a SMT process.

Referring to FIG. 6C, an electronic component 40 may be disposed on and attached to the substrate 10.

Referring to FIG. 6D, an encapsulant 50 may be formed on the substrate 10 to encapsulate the chip antenna 20, the conductive pillars 31 and 32, and the electronic component 40, to form an electronic device 6. The encapsulant 50 may be formed by a molding process and a grinding process. In some embodiments, the top surface of the chip antenna 20 and the top surface of the electronic component 40 may be exposed by the encapsulant 50. In some embodiments, a monopole antenna 60 may be disposed on the substrate 10 (not shown) and encapsulated by the encapsulant 50. The electronic device 6 shown in FIG. 6D may be an exemplary cross-section of the electronic device 1, 2, or 3.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a substrate; and
a chip antenna over the substrate at a first elevation with respect to the substrate, wherein the first elevation is greater than a thickness of the chip antenna, and wherein the chip antenna is configured to radiate a first signal through a first electrical path.

2. The electronic device of claim 1, further comprising:
a first conductive pillar disposed between the substrate and the chip antenna and connected to the chip antenna; and
a second conductive pillar spaced apart from the first conductive pillar and connected to the chip antenna.

3. The electronic device of claim 2, wherein the first electrical path includes the first conductive pillar, the chip antenna, and the second conductive pillar.

4. The electronic device of claim 2, wherein the first conductive pillar is substantially perpendicular to the substrate.

5. The electronic device of claim 2, further comprising a third conductive pillar spaced apart from the first conductive pillar and connected to the chip antenna.

6. The electronic device of claim 5, wherein the third conductive pillar is connected to a conductive pattern on the substrate, wherein the conductive pattern is configured to radiate a second signal through a second electrical path.

7. The electronic device of claim 1, further comprising an electronic component disposed on the substrate, wherein the electronic component has a bottom surface lower than a bottom surface of the chip antenna.

8. The electronic device of claim 1, further comprising an encapsulant disposed over the substrate, wherein a top surface of the encapsulant is substantially aligned with a top surface of the chip antenna.

9. An electronic device, comprising:
a first antenna configured to generate a first signal at a first frequency; and
a second antenna configured to generate a second signal at a second frequency different from the first frequency,
wherein the first antenna and the second antenna share an electrical path.

10. The electronic device of claim 9, wherein the first antenna is configured to generate the first signal through a first electrical path, and the second antenna is configured to generate the second signal through a second electrical path, wherein the second electrical path includes the first antenna, the second antenna, and a first conductive pillar connecting the first antenna and the second antenna.

11. The electronic device of claim 10, wherein the second electrical path is shorter than the first electrical path.

12. The electronic device of claim 9, further comprising an electronic component spaced apart from the first antenna by a clearance zone.

13. The electronic device of claim 12, wherein the second antenna is disposed within the clearance zone.

14. The electronic device of claim 9, wherein the first antenna is a chip antenna and the second antenna is a monopole antenna.

15. The electronic device of claim 14, wherein the monopole antenna is connected to the chip antenna through a first conductive pillar.

16. The electronic device of claim 15, wherein the monopole antenna extends in a direction substantially perpendicular to the first conductive pillar.

17. An electronic device, comprising:
a substrate;
a chip antenna disposed on the substrate at a first elevation with respect to the substrate; and
a monopole antenna disposed on the substrate at a second elevation with respect to the substrate, different from the first elevation.

18. The electronic device of claim 17, wherein the second elevation is lower than the first elevation.

19. The electronic device of claim 17, wherein the chip antenna is configured to carry a first current flowing toward a first direction, and the monopole antenna is configured to carry a second current flowing toward a second direction different from the first direction.

20. The electronic device of claim 19, wherein the second direction is opposite to the first direction.
